(19) United States
(12) Patent Application Publication
(10) Pub. No.: US 2005/0062087 A1
(43) Pub. Date: Mar. 24, 2005

(54) Chalcogenide phase-change non-volatile memory, memory device and method for fabricating the same

(76) Inventors: Yi-Chou Chen, Hsinchu (TW); Hsiang-Lan Lung, Hsinchu (TW)

Correspondence Address: J C PATENTS, INC., 4 VENTURE, SUITE 250, IRVINE, CA, 92618, US

(21) Appl. No.: 10/817,579

(22) Filed: Apr. 2, 2004

Related U.S. Application Data
(60) Provisional application No. 60/542,783, filed on Feb. 6, 2004.

(30) Foreign Application Priority Data
Sep. 19, 2003 (TW) 92125868

(51) Int. Cl. H01L 29/02

(52) U.S. Cl. 257/295

(57) ABSTRACT

A memory device adapted to a chalcogenide phase-change memory is disclosed. The memory device comprises a top electrode, a bottom electrode, and a phase-change thin film between the top electrode and the bottom electrode. The phase-change thin film is a chalcogenide (Ge-Sb-Te) alloy doped with Tin (Sn) therein. Tin (Sn) doped in the chalcogenide (Ge-Sb-Te) alloy can enhance the crystallization rate of the phase-change thin film for improving the operation speed of the memory.

### CROSS-REFERENCE TO RELATED APPLICATION

This application claims the priority benefits of U.S. provisional application titled “CHALCOGENIDE PHASE-CHANGE NON-VOLATILE MEMORY, MEMORY DEVICE AND METHOD FOR FABRICATING THE SAME” filed on Feb. 6. 2004. All disclosure of this application is incorporated herein by reference. This application also claims the priority benefit of Taiwan application serial no. 92125868, filed on Sep. 19, 2003.

### BACKGROUND OF THE INVENTION

1. Field of the Invention

The present invention relates to a memory device and a method for fabricating the same, and more particularly to a chalcogenide phase-change non-volatile memory and a memory device thereof and a method of fabricating the same.

2. Description of the Related Art

A non-volatile memory is a memory that can store data even if power is interrupted. A non-volatile memory which can provide multiple entry, retrieval and erasure of data, such as flash memory and nitride read only memory (NROM) has been widely used in personal computers and electronic devices.

Because of the demands on high level of integration and high speed in memory devices, a chalcogenide phase-change non-volatile memory, which have high level of integration, low operational power and high programming and read speeds and being integrable with CMOS process, are receiving more attention. As to more detail descriptions of a chalcogenide phase-change non-volatile memory, please refer to Stefan Lai, Tyler Lowrey, “OUM-A 180 nm Nonvolatile Memory Cell Element Technology For Stand Alone And Embedded Applications”, IEDM Digest, pp. 803-806, 2001.

A typical chalcogenide phase-change non-volatile memory uses chalcogenide (Ge-Sb-Te) as a storage media. Because chalcogenide is amorphous or crystalline under different annealing temperatures and has different resistances, amorphous chalcogenide having high resistance and crystalline chalcogenide having low resistance can be applied for representing “0” and “1”. Particularly, a phase change of chalcogenide is reversible. Therefore, memories using chalcogenide as a storage media can be programmed, read and erased repeatedly.

However, the crystallization rate of a chalcogenide thin film is reduced because of the reduction of the thickness of the film. To achieve high operational speed in a memory, in other words, the chalcogenide thin film has a high crystallization rate, the thickness of the film is increased. However, increasing the film thickness prevents a further increase of the device integration and a reduction of the size of the device.

### SUMMARY OF THE INVENTION

The object of the present invention, therefore, is to provide a chalcogenide phase-change non-volatile memory, and a memory device thereof and a method of fabricating the same. The operational speed of the chalcogenide phase-change non-volatile memory is enhanced without increasing the thickness of the chalcogenide thin film.

The present invention discloses a memory unit, which is applied to a chalcogenide phase-change non-volatile memory device. The memory unit comprises: a top electrode, a bottom electrode, and a phase-change thin film between the top electrode and the bottom electrode, wherein the phase-change thin film is a chalcogenide doped with an element therein, and the element enhances the crystallization rate of the chalcogenide. In a preferred embodiment, the element is, for example, Tin (Sn) and a mole ratio of the element within the chalcogenide is from about 0.1% to about 90%. It is preferred that the mole ratio of the element within the chalcogenide is lower than 10%.

The present invention discloses a method for fabricating a memory device, which is applied to a chalcogenide phase-change non-volatile memory. The method comprises: forming a bottom electrode; forming a phase-change thin film on the bottom electrode, wherein the phase-changed thin film is a chalcogenide doped with an element, and the element enhances the crystallization rate of the chalcogenide; and forming a top electrode on the phase-change thin film. The method of forming the phase-change thin film is performed by a sputtering process using a chalcogenide target, doped with the element therein or by a co-sputtering process using a target having the element and a chalcogenide target.

The present invention discloses a chalcogenide phase-change non-volatile memory device, comprising a word-line, a bit-line, a selective device, and a memory unit. The selective device, which is electrically coupled to the word-line and the bit-line and the memory device is electrically coupled to the selective device, wherein the memory unit comprises a top electrode, a bottom electrode and a phase-change thin film between the top electrode and the bottom electrode, and the phase-change thin film is a chalcogenide alloy doped with an element therein, the element enhancing the crystallization rate of the chalcogenide alloy. In a preferred embodiment, the element is, for example, Tin (Sn) and a mole ratio of the element within the chalcogenide alloy is from about 0.1% to about 90%. It is preferred that the mole ratio of the element within the chalcogenide alloy is lower than 10%.

In the chalcogenide phase-change non-volatile memory of the present invention, because the chalcogenide alloy within the phase-change thin film is doped with Sn which enhances the crystallization rate of the chalcogenide alloy, the operational speed of the memory is improved.

In order to make the aforementioned and other objects, features and advantages of the present invention understandable, a preferred embodiment accompanied with figures is described in detail below.

### BRIEF DESCRIPTION OF THE DRAWINGS

FIG. 1 is a schematic drawing showing a preferred embodiment of a chalcogenide phase-change non-volatile memory of the present invention.

FIG. 2, it is a schematic drawing showing a preferred memory device of the present invention.

### DESCRIPTION OF SOME EMBODIMENTS

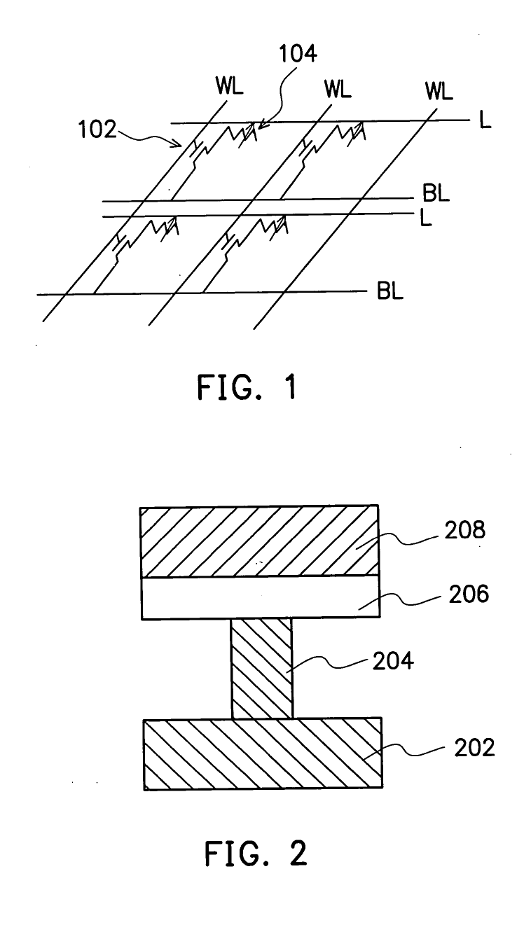

As shown in FIG. 1, it is a schematic drawing showing a preferred embodiment of a chalcogenide phase-change non-volatile memory of the present invention. Please referring to FIG. 1, the chalcogenide phase-change non-volatile memory device of the present invention is comprises of a plurality of memory cells.The chalcogenide phase-change non-volatile memory device includes word-lines, bit-lines, selective devices 102 and memory units 104. Each memory cell comprises a selective device 102 and a memory unit 104, and each selective device 102 is electrically coupled to a corresponding word-line and a corresponding bit-line. Therefore, each memory cell is controlled by a word-line and a bit-line. In a preferred embodiment, the selective device 102 is, for example, a metal-oxide-semiconductor (MOS) transistor. The word-line connects gates of MOS transistors in the same column; the bit-line connects sources of MOS transistors in the same row.

In addition, the memory unit 104 is electrically coupled to the selective device in each memory cell. In a preferred embodiment, the memory unit 104 is formed over the selective device 102, and an interlayer dielectric (ILD) is formed between these two devices. The drain of the selective device 102 is electrically coupled to the memory unit 104 by an interconnect structure. Therefore, the memory unit 104 is formed after the formation of the MOS transistor and before the formation of the interconnect structure, which belongs to the backend process of a semiconductor manufacturing process. A conductive wire L connects the memory units 104 in the same row.

The detail description of the memory unit 104 shown in FIG. 1 is described below. Please refer to FIG. 2, it is a schematic drawing showing a preferred memory device of the present invention. The memory unit comprises a top electrode 208, a bottom electrode 204 and a phase-change thin film 206 between the top electrode 208 and the bottom electrode 204. In a preferred embodiment, the bottom electrode 204 is a metal plug, such as a tungsten plug, and connects to a conductive wire 202, such as an aluminum wire. The bottom electrode 204 is electrically connected to the selective device 102 shown in FIG. 1 by the conductive wire 202 and the other conductive wire structures. The method of forming the bottom electrode 204 is performed by a traditional plug process. If the memory is fabricated with a 0.18 μm technology, the diameter of the bottom electrode 204 is, for example, about 0.22 μm.

In addition, the phase-change thin film 206 formed on the bottom electrode 204 is a storage media, wherein the phase-change thin film 206 is a chalcogenide alloy (Ge-Sb-Te, doped with an element therein, and the element enhances the crystallization rate of the chalcogenide alloy. In a preferred embodiment, the chalcogenide alloy is, for example, Ge2Sb2Te5, and the element doped therein is, for example, Tin (Sn). The mole ratio of the element within the chalcogenide alloy is from about 0.1% to about 90%. It is preferred that the mole ratio of the element within the chalcogenide alloy is lower than 10%. The phase-change thin film 206 can be formed by any process. For example, the phase-change thin film 206 can be formed by a sputtering process using a chalcogenide target doped with the element therein, or by a co-sputtering process using a chalcogenide target and another target doped with the element therein, or by a co-evaporation process using the element and chalcogenide alloy. In addition, the method of forming phase-change thin film 206 doped with the element therein includes an ion-implantation process, diffusion process, etc. If the memory is fabricated with a 0.18 μm technology, the thickness of the phase-change thin film 206 is, for example, about 55 nm.

Please referring to FIG. 2, the top electrode 208 formed on the phase-change thin film 206 is, for example, a titanium tungsten (TiW) alloy formed, for example, by depositing a metal film by a sputtering process and then patterning the metal film. If the memory is fabricated with a 0.18 μm technology, the thickness of the top electrode 208 is, for example, about 110 nm.

Therefore, the phase-change thin film of the chalcogenide phase-change non-volatile memory of the present invention use a chalcogenide alloy doped with an element which enhances the crystallization rate of the chalcogenide alloy, and improves the operational speed of the memory, including operations of set, reset, and read/write, and efficiency thereof.

Following is a comparison concerning electrical performances between two chalcogenide phase-change non-volatile memories, wherein the first memory uses undoped chalcogenide alloy and the second memory uses doped chalcogenide alloy.

TABLE 1

| | First memory | Second memory |
|---|---|---|
| | (with undoped | (with doped |
| | chalcogenide) | chalcogenide) |
| RESET | 40 ns | 10 ns |
| SET | 200 ns | 40 ns |
| Resistance Ratio of | >100 | >3 |
| RESET/SET | | |
| Crystalline Resistance | ˜50K Ohm | ˜4K Ohm |

In Table 1, the memory using a chalcogenide alloy doped with Sn has higher operational speeds of reset and set than those of the memory using undoped chalcogenide. Moreover, the memory using a chalcogenide alloy doped with Sn has a lower resistance ratio of RESET/SET and a lower crystalline resistance than those of the memory using an undoped chalcogenide alloy.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A memory device of chalcogenide phase-change non-volatile memory, comprising;
a top electrode;
a bottom electrode; and
a phase-change thin film between the top electrode and the bottom electrode, wherein the phase-change thin film is a chalcogenide alloy doped with an element therein, and the element enhances a crystallization rate of the chalcogenide alloy.

2. The memory device of claim 1, wherein the element includes Tin (Sn).

3. The memory device of claim 1, wherein a mole ratio of the element within the chalcogenide alloy is from about 0.1% to about 90%.

4. The memory device of claim 3, wherein the mole ratio of the element within the chalcogenide alloy is lower than 10%.

5. The memory device of claim 1, wherein the chalcogenide alloy is Ge₂Sb₂Te₅.

6. A method of fabricating a memory device of chalcogenide phase-change non-volatile memory, comprising;
forming a bottom electrode;
forming a phase-change thin film on the bottom electrode, wherein the phase-changed thin film is a chalcogenide alloy doped with an element, and the element enhances the crystallization rate of the chalcogenide alloy; and
forming a top electrode on the phase-change thin film.

7. The method of fabricating a memory device of claim 6, wherein the method of forming the phase-change thin film is performed by a sputtering process using a chalcogenide target doped with the element therein.

8. The method of fabricating a memory device of claim 6, wherein the method of forming the phase-change thin film is performed by a co-sputtering process using a target having the element and a chalcogenide target.

9. The method of fabricating a memory device of claim 6, wherein the method of forming the phase-change thin film of the chalcogenide alloy doped with the element therein is performed by an ion-implantation process.

10. The method of fabricating a memory device of claim 6, wherein the method of forming the phase-change thin film of the chalcogenide alloy doped with the element therein is performed by a diffusion process.

11. The method of fabricating a memory device of claim 6, wherein the method of forming the phase-change thin film is performed by a co-evaporation process using the chalcogenide alloy and the element.

12. The method of fabricating a memory device of claim 6, wherein the element includes Tin (Sn).

13. A chalcogenide phase-change non-volatile memory, comprising:
a word-line;
a bit-line, which is electrically coupled to the word-line;
a selective device, which is electrically coupled to the word-line and the bit-line; and
a memory device, which is electrically coupled to the selective device, wherein the memory device comprises a top electrode, a bottom electrode and a phase-change thin film between the top electrode and the bottom electrode, and the phase-change thin film is a chalcogenide alloy doped with an element therein, the element enhancing the crystallization rate of the chalcogenide alloy.

14. The chalcogenide phase-change non-volatile memory of claim 13, wherein the element includes Tin (Sn).

15. The chalcogenide phase-change non-volatile memory of claim 13, wherein a mole ratio of the element within the chalcogenide alloy is from about 0.1% to about 90%.

16. The chalcogenide phase-change non-volatile memory of claim 15, wherein the mole ratio of the element within the chalcogenide alloy is less than 10%.

17. The chalcogenide phase-change non-volatile memory of claim 13, wherein the chalcogenide alloy is Ge₂Sb₂Te₅.
